(19) United States
(12) Patent Application Publication
(10) Pub. No.: US 2012/0184113 A1
(43) Pub. Date: Jul. 19, 2012

(54) METHOD AND DEVICE FOR MANUFACTURING SILICON CARBIDE SUBSTRATE

(75) Inventors: Hiroki Inoue, Itami-shi (JP); Shin Harada, Osaka-shi (JP); Makoto Sasaki, Itami-shi (JP); Taro Nishiguchi, Itami-shi (JP); Kyoko Okita, Itami-shi (JP); Yasuo Namikawa, Itami-shi (JP)

(73) Assignee: Sumitomo Electric Industries, Ltd., Osaka-shi, Osaka (JP)

(21) Appl. No.: 13/395,793

(22) PCT Filed: Jan. 7, 2011
(86) PCT No.: PCT/JP2011/050142

§ 371 Date: Mar. 13, 2012

(30) Foreign Application Priority Data
Jun. 21, 2010 (JP) 2010-140768

(51) Int. Cl. H01L 21/30; H05B 3/02

(52) U.S. Cl. 438/799; 219/538; 257/E21.211

(57) ABSTRACT

A step of preparing a stack is performed to position each single-crystal substrate in a first single-crystal substrate group and a first base substrate face to face with each other, position each single-crystal substrate in a second single-crystal substrate group and a second base substrate face to face with each other, and stack the first single-crystal substrate group, the first base substrate, an insertion portion, the second single-crystal substrate group, and the second base substrate in one direction in this order. Next, the stack is heated so as to allow a temperature of the stack to reach a temperature at which silicon carbide can sublime and so as to form a temperature gradient in the stack with the temperature thereof getting increased in the above-described direction. In this way, silicon carbide substrates can be manufactured efficiently.

### TECHNICAL FIELD

The present invention relates to method and device for manufacturing a silicon carbide substrate.

### BACKGROUND ART

In recent years, silicon carbide substrates have been adopted as semiconductor substrates for use in manufacturing semiconductor devices. Silicon carbide has a band gap larger than that of silicon, which has been used more commonly. Hence, a semiconductor device employing a silicon carbide substrate advantageously has a large breakdown voltage, low on-resistance, and properties less likely to decrease in a high temperature environment.

In order to efficiently manufacture such semiconductor devices, the substrates need to be large in size to some extent. According to U.S. Pat. No. 7,314,520 (Patent Literature 1), a silicon carbide substrate of 76 mm (3 inches) or greater can be manufactured.

### CITATION LIST

### Patent Literature

PTL 1: U.S. Pat. No. 7,314,520

### SUMMARY OF INVENTION

### Technical Problem

Industrially, the size of a silicon carbide substrate is still limited to approximately 100 mm (4 inches). Accordingly, semiconductor devices cannot be efficiently manufactured using large substrates, disadvantageously. This disadvantage becomes particularly serious in the case of using a property of a plane other than the (0001) plane in silicon carbide of hexagonal system. Hereinafter, this will be described.

A silicon carbide substrate small in defect is usually manufactured by slicing a silicon carbide ingot obtained by growth in the (0001) plane, which is less likely to cause stacking fault. Hence, a silicon carbide substrate having a plane orientation other than the (0001) plane is obtained by slicing the ingot not in parallel with its grown surface. This makes it difficult to sufficiently secure the size of the substrate, or many portions in the ingot cannot be used effectively. For this reason, it is particularly difficult to effectively manufacture a semiconductor device that employs a plane other than the (0001) plane of silicon carbide.

Instead of increasing the size of such a silicon carbide substrate with difficulty as described above, it is considered to use a silicon carbide substrate having a single-crystal substrate group and a base substrate connected to each one in the single-crystal substrate group. Even if the base substrate has a high crystal defect density, problems are unlikely to take place. Hence, a large substrate can be prepared relatively readily. The size of the silicon carbide substrate can be increased by increasing the number of single-crystal substrates of the single-crystal substrate group, as required.

The present inventors have found that a method of recrystallizing sublimation gas, which is generated from the base substrate, on each one in the single-crystal substrate group can be used as a method for connecting each one in the single-crystal substrate group and the base substrate to each other. However, a method for efficiently manufacturing a plurality of silicon carbide substrates has not been sufficiently considered in manufacturing a silicon carbide substrate using the above-described method.

The present invention has been made in view of the above-described problem, and its object is to provide method and device for manufacturing a silicon carbide substrate, whereby silicon carbide substrates can be efficiently manufactured.

### Solution to Problem

A method for manufacturing a silicon carbide substrate in the present invention includes the following steps. There is prepared a stack including first and second single-crystal substrate groups each made of silicon carbide, first and second base substrates each made of silicon carbide, and an insertion portion made of a material having solid state at a sublimation temperature of silicon carbide. The step of preparing the stack is performed to position each single-crystal substrate in the first single-crystal substrate group and the first base substrate face to face with each other, position each single-crystal substrate in the second single-crystal substrate group and the second base substrate face to face with each other, and stack the first single-crystal substrate group, the first base substrate, the insertion portion, the second single-crystal substrate group, and the second base substrate in one direction in this order. Then, the stack is heated so as to allow a temperature of the stack to reach a temperature at which silicon carbide is able to sublime and so as to form a temperature gradient in the stack with the temperature thereof getting increased in the one direction.

According to the method for manufacturing the silicon carbide substrate in the present invention, the plural sets of single-crystal substrate groups and the plural sets of base substrates are stacked on one another and are heated, thereby manufacturing a plurality of silicon carbide substrates simultaneously. Further, before the heating, the insertion portion is disposed between the first base substrate and the second single-crystal substrate group, thereby preventing connection between different silicon carbide substrates. In this way, the silicon carbide substrates can be manufactured efficiently.

Preferably, the temperature gradient is not less than 0.1° C./mm and not more than 20° C./mm. When the temperature gradient is set at 0.1° C./mm or greater, the connection between the base substrate and the single-crystal substrate group can be developed more securely. Further, when the temperature gradient is 20° C. or smaller, the device for heating can be more simplified.

Preferably, the insertion portion includes a partition member for separating an entire portion of the second single-crystal substrate group and the first base substrate from each other. This prevents undesirable connection between different silicon carbide substrates more securely. More preferably, the partition member is made of one of carbon, molybdenum, tungsten, and metal carbide. Accordingly, the partition member can be provided with heat resistance to withstand the above-described heating. Further, the partition member can have reduced reactivity for silicon carbide.

Preferably, the insertion portion includes a protective film formed on each single-crystal substrate of the second single-crystal substrate group at its surface opposite to its surface that is to face the second base substrate. Accordingly, during the heating, the surface of the second single-crystal substrate group can be protected. More preferably, the protective film includes at least one of: a film formed by carbonizing an organic film; a carbon film; a diamondlike carbon film; and a diamond film. This can provide the protective film with heat resistance to withstand the above-described heating. This also allows the protective film to have reduced reactivity for silicon carbide.

A device for manufacturing a silicon carbide substrate in the present invention includes a container and a heating unit. The container is to accommodate therein a stack including first and second single-crystal substrate groups each made of silicon carbide, first and second base substrates each made of silicon carbide, and an insertion portion made of a material having solid state at a sublimation temperature of silicon carbide. The stack is configured such that each single-crystal substrate in the first single-crystal substrate group and the first base substrate are positioned face to face with each other, such that each single-crystal substrate in the second single-crystal substrate group and the second base substrate are positioned face to face with each other, and such that the first single-crystal substrate group, the first base substrate, the insertion portion, the second single-crystal substrate group, and the second base substrate are stacked on one another in one direction. The heating unit is to heat the stack so as to allow a temperature of the stack to reach a temperature at which silicon carbide is able to sublime and so as to form a temperature gradient in the stack with the temperature thereof getting increased in the one direction.

The phrase “first and second” used in the description above is not intended to exclude an embodiment having one or more additional objects in addition to the “first and second” objects.

### ADVANTAGEOUS EFFECTS OF INVENTION

As apparent from the description above, according to the present invention, silicon carbide substrates can be manufactured efficiently.

### BRIEF DESCRIPTION OF DRAWINGS

FIG. 1 is a plan view schematically showing a configuration of a silicon carbide substrate in a first embodiment of the present invention.

FIG. 2 is a schematic cross sectional view taken along a line II-II in FIG. 1.

FIG. 3 is a cross sectional view schematically showing a first step of a method for manufacturing the silicon carbide substrate in the first embodiment of the present invention.

FIG. 4 is a cross sectional view schematically showing a second step of the method for manufacturing the silicon carbide substrate in the first embodiment of the present invention.

FIG. 5 is a partial cross sectional view schematically showing a third step of the method for manufacturing the silicon carbide substrate in the first embodiment of the present invention.

FIG. 6 is a cross sectional view schematically showing one step of a method for manufacturing the silicon carbide substrate in the second embodiment of the present invention.

FIG. 7 is a partial cross sectional view schematically showing a configuration of a semiconductor device in a third embodiment of the present invention.

FIG. 8 is a schematic flowchart showing a method for manufacturing the semiconductor device in the third embodiment of the present invention.

FIG. 9 is a partial cross sectional view schematically showing a first step of the method for manufacturing the semiconductor device in the third embodiment of the present invention.

FIG. 10 is a partial cross sectional view schematically showing a second step of the method for manufacturing the semiconductor device in the third embodiment of the present invention.

FIG. 11 is a partial cross sectional view schematically showing a third step of the method for manufacturing the semiconductor device in the third embodiment of the present invention.

FIG. 12 is a partial cross sectional view schematically showing a fourth step of the method for manufacturing the semiconductor device in the third embodiment of the present invention.

FIG. 13 is a partial cross sectional view schematically showing a fifth step of the method for manufacturing the semiconductor device in the third embodiment of the present invention.

### DESCRIPTION OF EMBODIMENTS

The following describes embodiments of the present invention with reference to figures.

### First Embodiment

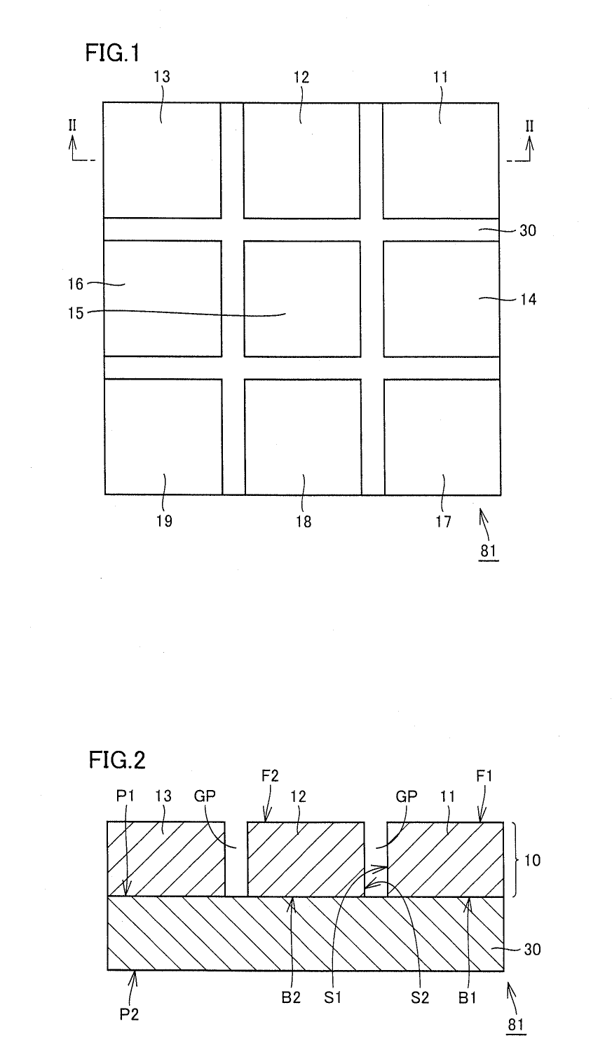

As shown in FIG. 1 and FIG. 2, a silicon carbide substrate 81 of the present embodiment has a base substrate 30 made of silicon carbide, and a single-crystal substrate group 10 made of silicon carbide. Single-crystal substrate group 10 has single-crystal substrates 11-19.

Each of single-crystal substrates 11-19 has a backside surface and a front-side surface opposite to each other, and has side surfaces connecting the backside surface and the front-side surface to each other. For example, single-crystal substrate 11 has a backside surface B1 and a front-side surface F1 opposite to each other, as well as a side surface S1 connecting backside surface B1 and front-side surface F1 to each other. Single-crystal substrate 12 has a backside surface B2 and a front-side surface F2 opposite to each other, as well as a side surface S2 connecting backside surface B2 and front-side surface F2 to each other.

Base substrate 30 has a main surface P1 and a main surface P2 opposite to each other. Further, each of single-crystal substrates 11-19 is disposed on base substrate 30. Specifically, each of the backside surfaces (backside surfaces B1, B2, and the like) of single-crystal substrates 11-19 is connected to main surface P1 of base substrate 30. Furthermore, gaps GP are formed between adjacent ones of single-crystal substrates 11-19. Thus, for example, side surfaces S1 and S2 face each other with a gap GP interposed therebetween. It should be noted that gaps GP do not need to separate single-crystal substrates 11-19 from one another completely. For example, side surface S1 may have a portion in contact with a portion of side surface S2.

As described above, main surface P1 of base substrate 30 connects the backside surfaces (backside surfaces B1, B2, and the like) of single-crystal substrates 11-19 to one another, whereby single-crystal substrates 11-19 are fixed to one another. Single-crystal substrates 11-19 have front-side surfaces exposed on the same plane (front-side surfaces F1, F2, and the like). This allows silicon carbide substrate 81 to have a surface larger than that of each of single-crystal substrates 11-19. Hence, in the case of using silicon carbide substrate 81, semiconductor devices can be manufactured more effectively than in the case of using each of single-crystal substrates 11-19 solely.

The following describes a method for manufacturing a plurality of silicon carbide substrates 81. In the present embodiment, it will be illustrated that three silicon carbide substrates 81 are simultaneously manufactured.

First, as materials for each of the plurality of silicon carbide substrates 81, three base substrates 30 and three sets of single-crystal substrate groups 10 are prepared. Specifically, for example, each one in each single-crystal substrate group 10 is prepared by slicing, along the (0-33-8) plane, a SiC ingot grown in the (0001) plane in the hexagonal system. In this case, preferably, the (0-33-8) plane side is employed for the front-side surface thereof, and the (03-38) plane side is employed for the backside surface thereof. Further, each of the backside surfaces of those in single-crystal substrate group 10 is preferably a surface formed by the above-described slicing (so-called “as-sliced surface”), i.e., a surface not polished after the slicing. Each one in single-crystal substrate group 10 has a thickness of, for example, 400 μm. Each of base substrates 30 has a thickness of, for example, 400 μm.

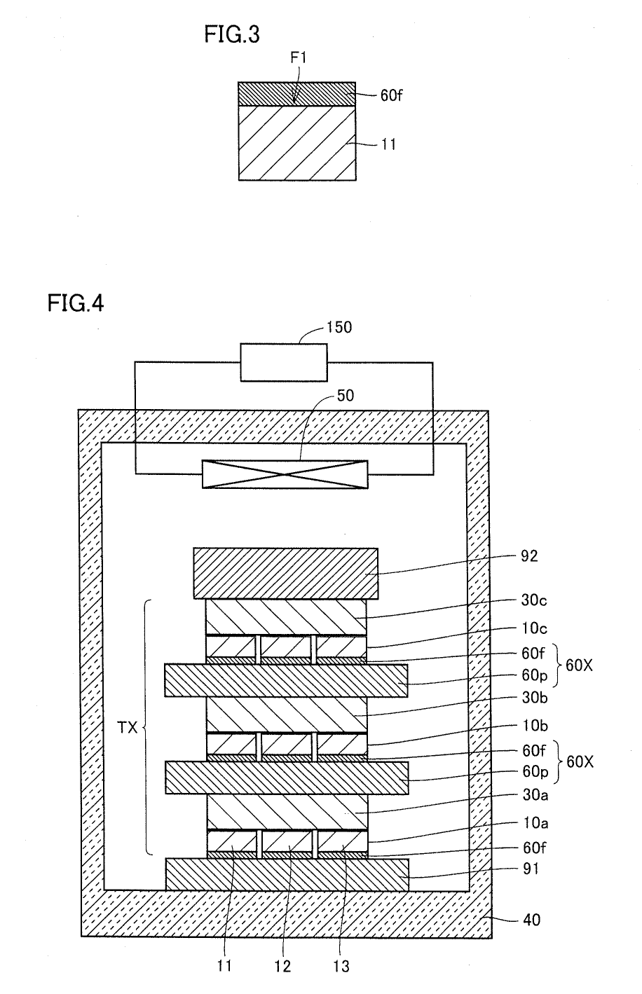

Referring to FIG. 3, each of single-crystal substrates 11-19 (only single-crystal substrate 11 is illustrated in FIG. 3) has its front-side surface (front-side surface F1 in the case of single-crystal substrate 11) having a protective film 60f formed thereon. Protective film 60f is made of a material having a solid state at the sublimation temperature of silicon carbide. Specifically; protective film 60f includes at least one of: a film formed by carbonizing an organic film; a carbon film; a diamondlike carbon film; and a diamond film. The film formed by carbonizing the organic film can be readily formed by applying and carbonizing a fluid containing an organic substance. An example of such a fluid is a photoresist or a carbon adhesive agent.

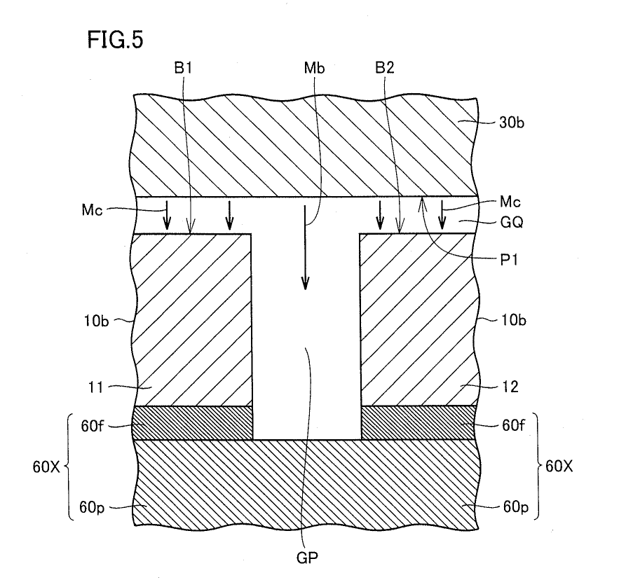

Referring to FIG. 4, a heating device is prepared. The heating device includes a heat insulation container 40, first and second heating members 91, 92, a heater 50, and a heater power source 150. Heat insulation container 40 is formed of a highly thermally insulating material. Heater 50 is, for example, an electric resistance heater. First and second heating members 91, 92 have a function of absorbing heat emitted from heater 50 and emitting the absorbed heat so as to heat base substrates 30 and single-crystal substrate groups 10. Each of first and second heating members 91, 92 is formed of, for example, graphite with a small porosity.

Next, a stack TX is prepared which includes first to third single-crystal substrate groups 10a-10c, and first to third base substrates 30a-30c, and insertion portions 60X. Here, first to third single-crystal substrate groups 10a-10c and first to third base substrates 30a-30c correspond to the above-described three single-crystal substrate groups 10 and three base substrates 30. Further, each of insertion portions 60X refers to a portion including protective film 60f formed on each of single-crystal substrates 11-19 and a partition member 60p.

Partition member 60p is formed of a material having solid state at the sublimation temperature of silicon carbide, preferably, is formed of one of carbon, molybdenum, tungsten, and metal carbide. Partition member 60p has a thickness of preferably 100 nm to 10 mm. As partition member 60p, there can be used, for example, a carbon plate having a thickness of approximately 1 mm, or a flexible film containing carbon as its main component and having a thickness of 0.2 mm to 1 mm.

A step of preparing stack TX is specifically performed to position the backside surface of each one in first single-crystal substrate group 10a and first base substrate 30a face to face with each other, position the backside surface of each one in second single-crystal substrate group 10b and the second base substrate face to face with each other, and position the backside surface of each one in third single-crystal substrate group 10c and third base substrate 30c face to face with each other. Single-crystal substrates 11-19 provided in each of first to third single-crystal substrate groups 10a-10c are arranged in the form of, for example, a matrix as shown in FIG. 1. Preferably, in each of first to third single-crystal substrate groups 10a-10c, a minimum interval between single-crystal substrates 11-19 is set at 5 mm or smaller, more preferably, 1 mm or smaller, further preferably, 100 μm or smaller, particularly preferably, 10 μm or smaller.

In addition, this step is performed to stack first single-crystal substrate group 10a, first base substrate 30a, first insertion portion 60X, second single-crystal substrate group 10b, second base substrate 30b, second insertion portion 60X, third single-crystal substrate group 10c, and third base substrate 30c in one direction (upwardly in FIG. 4). First insertion portion 60X is disposed to separate an entire portion of second single-crystal substrate group 10b and first base substrate 30a from each other, and second insertion portion 60X is disposed to separate an entire portion of third single-crystal substrate group 10c and second base substrate 30b from each other.

Such a stack TX is placed on first heating member 91. On stack TX, second heating member 92 is placed. In this way, stack TX is sandwiched between first and second heating members 91, 92. Next, stack TX thus sandwiched between first and second heating members 91, 92 is accommodated in heat insulation container 40. In doing so, it is preferable to dispose second heating member 92 at a location closer to heater 50 relative to first heating member 91.

Next, the atmosphere in heat insulation container 40 is adapted to be an atmosphere obtained by reducing the pressure of atmospheric air, or an inert gas atmosphere. An exemplary inert gas usable is a noble gas such as He or Ar; a nitrogen gas; or a mixed gas of the noble gas and nitrogen gas. The pressure in heat insulation container 40 is preferably set at 0.01-10⁴ Pa, and more preferably at 0.1-10⁴ Pa.

Next, heater 50 heats stack TX by means of first and second heating members 91, 92. This heating is performed to allow stack TX to reach a temperature at which silicon carbide can sublime, for example, at a temperature not less than 1800° C. and not more than 2500° C., more preferably, at a temperature not less than 2000° C. and not more than 2300° C. Heating time is set at, for example, 1 to 24 hours.

This heating is also performed to form a temperature gradient in stack TX with the temperature getting increased in the above-described one direction (upward in FIG. 4). Such a temperature gradient can be provided by, for example, disposing heater 50 at a location closer to second heating member 92 relative to first heating member 91. Further, this temperature gradient is preferably not less than 0.1° C./mm and not more than 20° C./mm.

Further, referring to FIG. 5, at the stage of starting the heating, first to third base substrates 30a-30c are only placed on first to third single-crystal substrate groups 10a-10c respectively, and are not connected thereto. Thus, when viewed microscopically, a space GQ exists between each of the backside surfaces (backside surfaces B1 and B2) of respective ones in second single-crystal substrate group 10b and main surface P1 of second base substrate 30b. Space GQ has an average height (dimension in the vertical direction in FIG. 5) of several ten μm, for example.

In space GQ, the above-described temperature gradient causes mass transfer of silicon carbide due to sublimation and recrystallization thereof. Specifically, sublimation gas of silicon carbide is formed from second base substrate 30b, and this gas is recrystallized on each of the backside surfaces of the respective ones in second single-crystal substrate group 10b. Namely, in space GQ, mass transfer takes place from second base substrate 30b to each one in second single-crystal substrate group 10b as indicated by arrows Mc in the figure. This mass transfer allows second base substrate 30b to be connected to each one in second single-crystal substrate group 10b.

Further, also in gap GP between the respective ones in second single-crystal substrate group 10b, the above-described temperature gradient causes mass transfer of silicon carbide due to sublimation and recrystallization. Specifically, from second base substrate 30b, sublimation gas of silicon carbide is formed. This gas travels from second base substrate 30b into gap GP as indicated by an arrow Mb in the figure. The traveling of the sublimation gas is blocked by partition member 60p, and therefore does not go beyond partition member 60p to reach first base substrate 30a (FIG. 4). This prevents the sublimation gas from adhering second single-crystal substrate group 10b and first base substrate 30a to each other, i.e., from connecting different silicon carbide substrates 81 to each other.

In FIG. 5, the connection between second single-crystal substrate group 10b and second base substrate 30b is illustrated, but connection between first single-crystal substrate group 10a and first base substrate 30a and connection between third single-crystal substrate group 10c and third base substrate 30c are also attained in a similar manner.

Next, from heat insulation container 40, stack TX is taken out. Then, partition member 60p is removed. Partition member 60p can be readily removed by peeling it. Thereafter, protective film 60f is removed. Protective film 60f is removed by, for example, polishing or etching. Accordingly, the plurality of silicon carbide substrates 81 (FIG. 1 and FIG. 2) can be manufactured simultaneously.

According to the method for manufacturing silicon carbide substrate 81 (FIG. 2) of the present embodiment, stack TX having the plural sets of single-crystal substrate groups 10 and base substrates 30 is heated (FIG. 4), thereby simultaneously manufacturing the plurality of silicon carbide substrates 81. Further, before the heating, insertion portion 60X is disposed between first base substrate 30a and second single-crystal substrate group 10b, thereby preventing undesirable connection between different silicon carbide substrates 81. In this way, silicon carbide substrates 81 can be manufactured efficiently.

Further, the front-side surface of each one in each single-crystal substrate group 10 is protected by protective film 60f. This prevents sublimation of the front-side surface of single-crystal substrate group 10 or reaction thereof with other substances. Accordingly, silicon carbide substrates 81 obtained can have surfaces improved in quality. Further, when protective film 60f includes at least one of a film formed by carbonizing an organic film; a carbon film; a diamondlike carbon film; and a diamond film, protective film 60f can be provided with heat resistance to withstand the above-described heating. This also allows protective film 60f to have reduced reactivity for silicon carbide.

Further, when partition member 60p is formed of one of carbon, molybdenum, tungsten, and metal carbide, partition member 60p can be provided with heat resistance to withstand the above-described heating. This also allows partition member 60p to have reduced reactivity for silicon carbide.

When the temperature gradient in the heating is set at 0.1° C./mm or greater, the connection between the base substrate and the single-crystal substrate group can be developed more securely. Further, when the temperature gradient is 20° C. or smaller, the device for heating can be more simplified.

Further, when partition member 60p has a thickness of 100 nm or greater, the sublimation gas can be prevented from passing through a porous portion of partition member 60p. Further, when the thickness thereof is 10 mm or smaller, the space within heat insulation container 40 can be used effectively.

Preferably, base substrate 30 has an impurity concentration higher than that of each in single-crystal substrate group 10. In other words, the impurity concentration of base substrate 30 is relatively high and the impurity concentration of each one in single-crystal substrate group 10 is relatively low. Since the impurity concentration of base substrate 30 is thus high, the resistivity of base substrate 30 can be small, thereby reducing a resistance for current flowing in silicon carbide substrate 81. Meanwhile, since the impurity concentration of each one in single-crystal substrate group 10 is thus low, the crystal defect thereof can be reduced more readily. As the impurity, nitrogen or phosphorus can be used, for example.

The crystal structure of silicon carbide of each single-crystal substrate in single-crystal substrate group 10 is preferably of hexagonal system, and is more preferably of 4H type or 6H type. More preferably, the front-side surface (front-side surface F1) has an off angle of not less than 50° and not more than 65° relative to the (000-1) plane of the single-crystal substrate. More preferably, the off orientation of the front-side surface forms an angle of 5° or smaller with the <1-100> direction of the single-crystal substrate. More preferably, the front-side surface has an off angle of not less than −3° and not more than 5° relative to the (0-33-8) plane in the <1-100> direction of the single-crystal substrate. Utilization of such a crystal structure achieves high channel mobility in a semiconductor device that employs silicon carbide substrate 81. It should be noted that the “off angle of the front-side surface relative to the (0-33-8) plane in the <1-100> direction” refers to an angle formed by an orthogonal projection of a normal line of the front-side surface to a projection plane defined by the <1-100> direction and the <0001> direction, and a normal line of the (0-33-8) plane. The sign of positive value corresponds to a case where the orthogonal projection approaches in parallel with the <1-100> direction whereas the sign of negative value corresponds to a case where the orthogonal projection approaches in parallel with the <0001> direction. Further, as a preferable off orientation of the front-side surface, the following off orientation can be employed apart from those described above: an off orientation forming an angle of 5° or smaller relative to the <11-20> direction of single-crystal substrate 11.

In the present embodiment, it has been illustrated that three silicon carbide substrates 81 are simultaneously manufactured using three sets of single-crystal substrate groups 10 and three sets of base substrates 30, but the number of the sets is any number not less than 2 as long as stack TX can be heated to an appropriate temperature and the temperature gradient in stack TX is appropriate. For example, in experiments for two sets, 30 sets, and 50 sets, it was confirmed that base substrates 30 and single-crystal substrate groups 10 were connected to one another in all the sets.

Further, when the front-side surface of each one in single-crystal substrate group 10 and the surface of partition member 60p both have high surface smoothness, the front-side surface of each one in single-crystal substrate group 10 can be protected by being tightly attached to each other. Hence, protective film 60f may not be formed.

### Second Embodiment

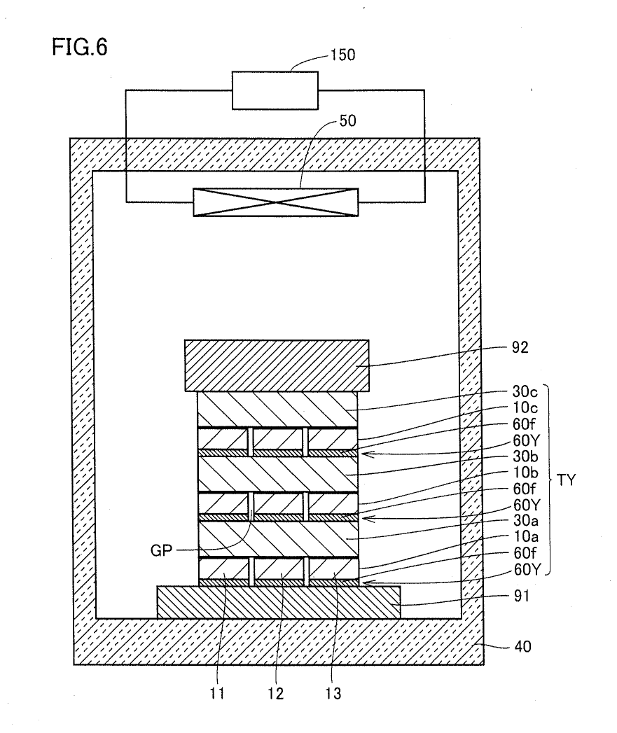

Referring to FIG. 6 mainly, in the present embodiment, a stack TY is used instead of stack TX (FIG. 4: the first embodiment). In stack TY, each insertion portion 60Y has protective film 60f but does not have partition member 60p (FIG. 4).

Apart from the configuration described above, the configuration of the present embodiment is substantially the same as the configuration of the first embodiment. Hence, the same or corresponding elements are given the same reference characters and are not described repeatedly.

According to the present embodiment, partition member 60p (FIG. 4) does not need to be used. Hence, the stacking height of stack TY (the dimension in the longitudinal direction in FIG. 6) can be smaller by the height of partition member 60p. Accordingly, the space within heat insulation container 40 can be used more effectively.

In order to prevent second single-crystal substrate group 10b and first base substrate 30a from being attached to each other due to recrystallization of sublimation gas produced in gap GP, gap GP is adapted to be sufficiently narrow. In other words, the present embodiment is suitable in the case where gap GP is narrow.

### Third Embodiment

In the present embodiment, the following describes manufacturing of a semiconductor device employing silicon carbide substrate 81 (FIG. 1 and FIG. 2). For ease of description, only single-crystal substrate 11 of single-crystal substrates 11-19 provided in silicon carbide substrate 81 may be explained, but each of the other single-crystal substrates 12-19 is handled in substantially the same manner.

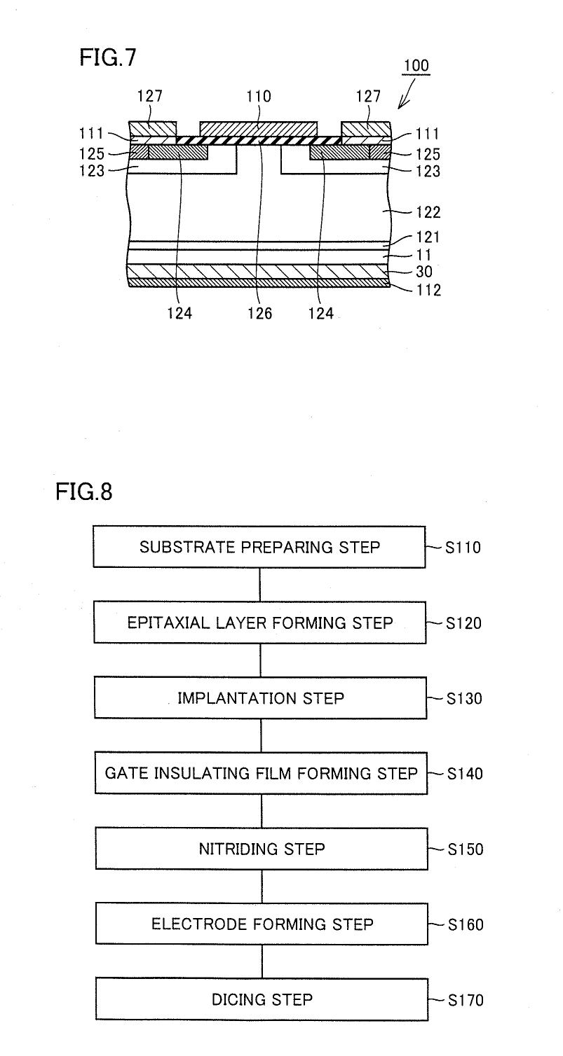

Referring to FIG. 7, a semiconductor device 100 of the present embodiment is a DiMOSFET (Double Implanted Metal Oxide Semiconductor Field Effect Transistor) of vertical type, and has a base substrate 30, a single-crystal substrate 11, a buffer layer 121, a breakdown voltage holding layer 122, p regions 123, n⁺ regions 124, p⁺ regions 125, an oxide film 126, source electrodes 111, upper source electrodes 127, a gate electrode 110, and a drain electrode 112. Semiconductor device 100 has a planar shape (shape when viewed from upward in FIG. 7) of, for example, a rectangle or a square with sides each having a length of 2 mm or greater.

Drain electrode 112 is provided on base substrate 30 and buffer layer 121 is provided on single-crystal substrate 11. With this arrangement, a region in which flow of carriers is controlled by gate electrode 110 is disposed not in base substrate 30 but in single-crystal substrate 11.

Each of base substrate 30, single-crystal substrate 11, and buffer layer 121 has n type conductivity. Impurity with n type conductivity in buffer layer 121 has a concentration of, for example, 5×10¹⁷ cm⁻³. Further, buffer layer 121 has a thickness of, for example, 0.5 μm.

Breakdown voltage holding layer 122 is formed on buffer layer 121, and is made of SiC with n type conductivity. For example, breakdown voltage holding layer 122 has a thickness of 10 μM, and includes a conductive impurity of n type at a concentration of 5×10¹⁵ cm⁻³.

Breakdown voltage holding layer 122 has a surface in which the plurality of p regions 123 of p type conductivity are formed with a space therebetween. In each of p regions 123, an n⁺ region 124 is formed at the surface layer of p region 123. Further, at a location adjacent to n⁺ region 124, a p⁺ region 125 is formed. An oxide film 126 is formed on a portion of breakdown voltage holding layer 122, which is exposed from between the plurality of p regions 123. Specifically, oxide film 126 is formed to extend on n⁺ region 124 in one p region 123, p region 123, the exposed portion of breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

The maximum value of nitrogen atom concentration is 1×10²¹ cm⁻³ or greater in a region distant away by not more than 10 nm from an interface between oxide film 126 and each semiconductor layer, i.e., each of n⁺ region 124, p⁺ region 125, p region 123, and breakdown voltage holding layer 122. This achieves improved mobility particularly in a channel region below oxide film 126 (a contact portion of each p region 123 with oxide film 126 between each of n⁺ regions 124 and breakdown voltage holding layer 122).

The following describes a method for manufacturing a semiconductor device 100. First, in a substrate preparing step (step S110: FIG. 8), silicon carbide substrate 81 (FIG. 1 and FIG. 2) is prepared.

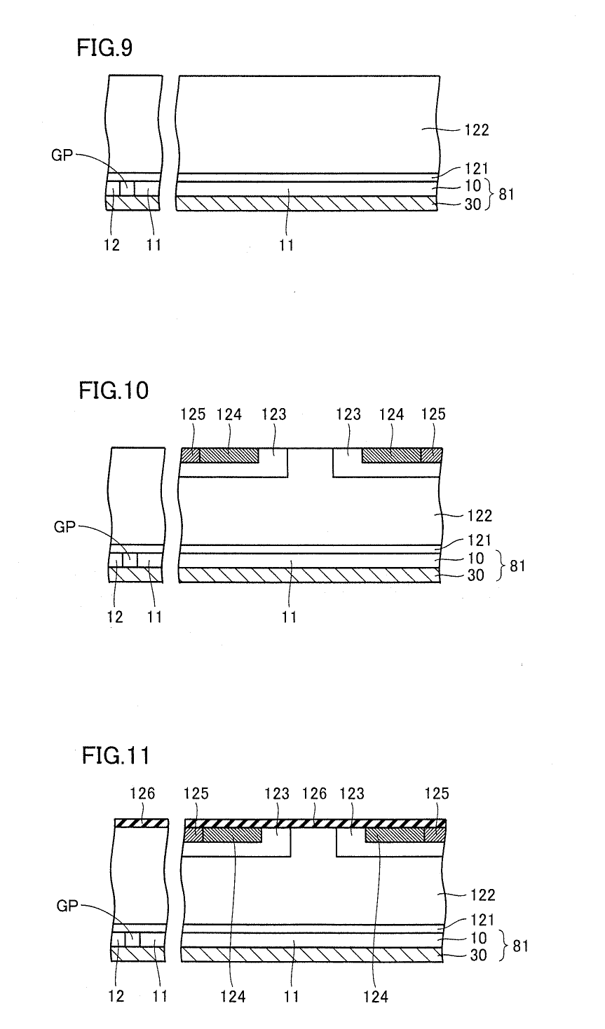

Referring to FIG. 9, in an epitaxial layer forming step (step S120: FIG. 8), buffer layer 121 and breakdown voltage holding layer 122 are formed as follows.

Buffer layer 121 is formed on the front-side surface of single-crystal substrate group 10. Buffer layer 121 is made of SiC of n type conductivity, and is an epitaxial layer having a thickness of 0.5 μM, for example. Buffer layer 121 has a conductive impurity at a concentration of, for example, 5×10¹⁷ cm⁻³.

Next, breakdown voltage holding layer 122 is formed on buffer layer 121. Specifically, a layer made of SiC of n type conductivity is formed using an epitaxial growth method. Breakdown voltage holding layer 122 has a thickness of, for example, 10 μm. Further, breakdown voltage holding layer 122 includes an impurity of n type conductivity at a concentration of, for example, 5×10¹⁵ cm⁻³.

Referring to FIG. 10, an implantation step (step S130: FIG. 8) is performed to form p regions 123, n⁺ regions 124, and p⁺ regions 125 as follows.

First, an impurity of p type conductivity is selectively implanted into portions of breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

Referring to FIG. 11, a gate insulating film forming step (step S140: FIG. 8) is performed. Specifically, oxide film 126 is formed to cover breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitriding step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Next, an electrode forming step (step S160: FIG. 8) is performed to form source electrodes 111 and drain electrode 112 in the following manner.

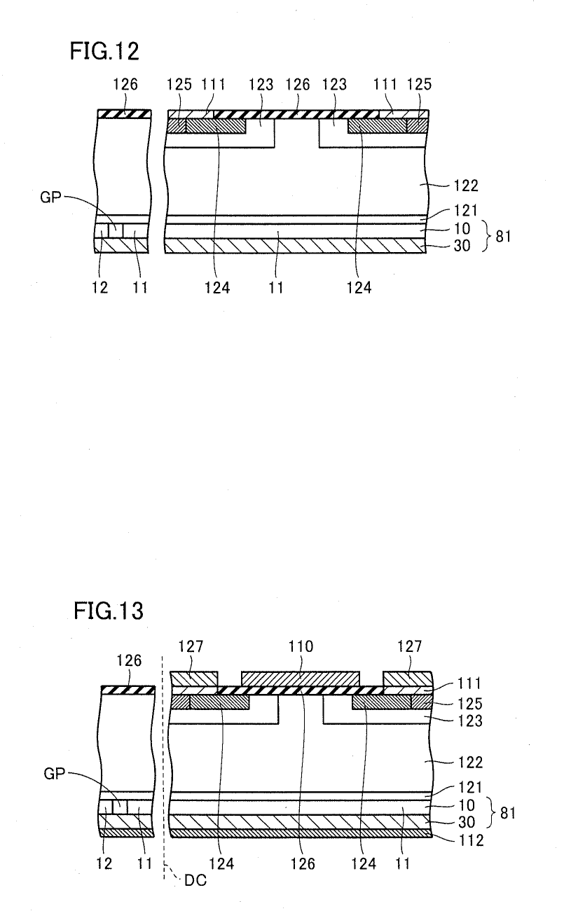

Referring to FIG. 12, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 13, upper source electrodes 127 are formed on source electrodes 111. Further, gate electrode 110 is formed on oxide film 126. Further, drain electrode 112 is formed on the backside surface of silicon carbide substrate 81.

Next, in a dicing step (step S170: FIG. 8), dicing is performed as indicated by a broken line DC. Accordingly, a plurality of semiconductor devices 100 (FIG. 7) are obtained by the cutting.

It should be noted that a configuration may be employed in which conductivity types are opposite to those in each of the foregoing embodiments. Namely, a configuration may be employed in which p type and n type are replaced with each other. Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

10: single-crystal substrate group; 10a-10c: first to third single-crystal substrate groups; 11-19: single-crystal substrate; 30: base substrate; 30a-30c: first to third base substrates; 40: heat insulation container; 50: heater; 91: first heating member; 92: second heating member; 150: heater power source; TX, TY: stack.

1. A method for manufacturing a silicon carbide substrate, comprising the steps of:
preparing a stack including first and second single-crystal substrate groups each made of silicon carbide, first and second base substrates each made of silicon carbide, and an insertion portion made of a material having solid state at a sublimation temperature of silicon carbide,
the step of preparing said stack being performed to position each single-crystal substrate in said first single-crystal substrate group and said first base substrate face to face with each other, position each single-crystal substrate in said second single-crystal substrate group and said second base substrate face to face with each other, and stack said first single-crystal substrate group, said first base substrate, said insertion portion, said second single-crystal substrate group, and said second base substrate in one direction in this order; and
heating said stack so as to allow a temperature of said stack to reach a temperature at which silicon carbide is able to sublime and so as to form a temperature gradient in said stack with the temperature thereof getting increased in said one direction.

2. The method for manufacturing the silicon carbide substrate according to claim 1, wherein said temperature gradient is not less than 0.1° C./mm and not more than 20° C./mm.

3. The method for manufacturing the silicon carbide substrate according to claim 1, wherein said insertion portion includes a partition member for separating an entire portion of said second single-crystal substrate group and said first base substrate from each other.

4. The method for manufacturing the silicon carbide substrate according to claim 3, wherein said partition member is made of one of carbon, molybdenum, tungsten, and metal carbide.

5. The method for manufacturing the silicon carbide substrate according to claim 1, wherein said insertion portion includes a protective film formed on each single-crystal substrate of said second single-crystal substrate group at its surface opposite to its surface that is to face said second base substrate.

6. The method for manufacturing the silicon carbide substrate according to claim 5, wherein said protective film includes at least one of: a film formed by carbonizing an organic film; a carbon film; a diamondlike carbon film; and a diamond film.

7. A device for manufacturing a silicon carbide substrate, comprising:
a container for accommodating therein a stack including first and second single-crystal substrate groups each made of silicon carbide, first and second base substrates each made of silicon carbide, and an insertion portion made of a material having solid state at a sublimation temperature of silicon carbide,
said stack being configured such that each single-crystal substrate in said first single-crystal substrate group and said first base substrate are positioned face to face with each other, such that each single-crystal substrate in said second single-crystal substrate group and said second base substrate are positioned face to face with each other, and such that said first single-crystal substrate group, said first base substrate, said insertion portion, said second single-crystal substrate group, and said second base substrate are stacked on one another in one direction; and
a heating unit for heating said stack so as to allow a temperature of said stack to reach a temperature at which silicon carbide is able to sublime and so as to form a temperature gradient in said stack with the temperature thereof getting increased in said one direction.
